(19) United States
(12) Patent Application Publication
(10) Pub. No.: US 2017/0178945 A1
(43) Pub. Date: Jun. 22, 2017

(54) SUBSTRATE PROCESSING SYSTEM AND SUBSTRATE PROCESSING METHOD

(71) Applicant: SAMSUNG ELECTRONICS CO., LTD., Suwon-si (KR)

(72) Inventors: Won-Guk SEO, Gunpo-Si (KR); Yong-Won CHOI, Yongin-Si (KR); Sang-Jin LEE, Cheonan-Si (KR); Yong-Bum JUNG, Cheonan-Si (KR); Seok HEO, Hwaseong-Si (KR)

(73) Assignee: SEMES CO. LTD., Cheonan-Si (KR)

(21) Appl. No.: 15/348,208

(22) Filed: Nov. 10, 2016

(30) Foreign Application Priority Data
Dec. 22, 2015 (KR) 10-2015-0183553

(51) Int. Cl. H01L 21/687; C23C 16/50; C23C 16/455; B05D 1/00; H01L 21/67; C23C 16/46

(52) U.S. Cl. CPC H01L 21/68707; H01L 21/67103; C23C 16/46; C23C 16/463; C23C 16/45544; B05D 1/005; C23C 16/50

(57) ABSTRACT

A substrate processing system includes an index module including wafer carriers. First and second heat processing units are disposed adjacent to the index module. Each of the first and second heat processing units includes a plurality of first heat processing plates sequentially stacked. First and second transfer robots are disposed adjacent to the first and second heat processing units, respectively. Each of the first and second transfer robots is movable along a vertical transfer path and to rotate. First and second coating units are disposed adjacent to first sides of the first and second transfer robots, respectively. Each of the first and second coating units includes a plurality of coating devices sequentially stacked. First and second bake units are disposed adjacent to second sides of the first and second transfer robots, respectively. Each of the first and second bake units includes a plurality of second heat processing plates sequentially stacked.

### CROSS-REFERENCE TO RELATED APPLICATION

This application claims priority under 35 U.S.C. §119 to Korean Patent Application No. 10-2015-0183553, filed on Dec. 22, 2015 in the Korean Intellectual Property Office (KIPO), the disclosure of which is incorporated by reference herein in its entirety.

### TECHNICAL FIELD

Exemplary embodiments of the present inventive concept relate to a substrate processing system, and more particularly to a substrate processing method.

### DISCUSSION OF RELATED ART

A double patterning process may be performed to form minute patterns having a fine width of about 20 nm or less. In the double patterning process, a sacrificial layer (e.g., a mold layer) may be formed for forming a mask pattern. The sacrificial layer may include a spin on hardmask (SOH) layer.

In a conventional CVD equipment or spinner equipment, a spin coater may be used to form the SOH layer. The conventional equipment may include a transfer robot which travels along a track to transfer a wafer. Thus, a transfer speed of the transfer robot may be increased to increase substrate throughput, and particles and vibrations on the robot may be generated and a lifespan of the transfer robot may be decreased due to a high travelling speed.

### SUMMARY

Exemplary embodiments of the present inventive concept provide a substrate processing system having an increased substrate throughput.

Exemplary embodiments of the present inventive concept provide a method of processing a substrate using the substrate processing system.

According to one or more exemplary embodiments of the present inventive concept, a substrate processing system includes an index module including a plurality of wafer carriers. Each wafer carrier is configured to support a wafer. First and second heat processing units are disposed adjacent to the index module. Each of the first and second heat processing units includes a plurality of first heat processing plates sequentially stacked in a vertical direction. First and second transfer robots are disposed adjacent to the first and second heat processing units, respectively. Each of the first and second transfer robots is configured to be movable along a vertical transfer path. Each of the first and second transfer robots is configured to rotate. First and second coating units are disposed adjacent to first sides of the first and second transfer robots, respectively. Each of the first and second coating units includes a plurality of coating devices sequentially stacked in the vertical direction. First and second bake units are disposed adjacent to second sides of the first and second transfer robots, respectively. Each of the first and second bake units includes a plurality of second heat processing plates sequentially stacked in the vertical direction.

According to one or more exemplary embodiments of the present inventive concept, a substrate processing system includes first and second heat processing units disposed adjacent to an index module. Each of the first and second heat processing units includes a plurality of first heat processing plates sequentially stacked in a vertical direction. First and second transfer robots are spaced apart from the first and second heat processing units in a first direction. Each of the first and second transfer robots is configured to be movable along a vertical transfer path. Each of the first and second transfer robots is configured to rotate. First and second coating units are spaced apart from the first and second transfer robots in a second direction. Each of the first and second coating units includes a plurality of coating devices sequentially stacked in the vertical direction. First and second bake units are spaced apart from the first and second transfer robots in a third direction different from the second direction. Each of the first and second bake units includes a plurality of second heat processing plates sequentially stacked in the vertical direction.

According to one or more exemplary embodiments of the present inventive concept, there is provided a substrate processing method including transferring wafers to each of first and second heat processing units disposed adjacent to a side of an index module. The method includes transferring the wafers from the first and second heat processing units to first and second coating units, respectively, by first and second transfer robots movable along a vertical transfer path. The first and second coating units are disposed adjacent to first sides of the first and second transfer robots, respectively. Each of the first and second coating units includes a plurality of coating devices sequentially stacked in a vertical direction. A material layer is coated on each of the wafers in the first and second coating units. The wafers are transferred from the first and second coating units to first and second bake units, respectively, by the first and second transfer robots. The first and second bake units are disposed adjacent to second sides of the first and second transfer robots, respectively. Each of the first and second bake units includes a plurality of heat processing plates sequentially stacked in the vertical direction. The method includes baking the coated material layer on each of the wafers in the first and second bake units.

### BRIEF DESCRIPTION OF THE DRAWINGS

The above and other features of the present inventive concept will become more apparent by describing in detail exemplary embodiments thereof with reference to the accompanying drawings, in which:

FIG. 1 is a perspective view illustrating a substrate processing system according to one or more exemplary embodiments of the present inventive concept.

FIG. 2 is a plan view illustrating the substrate processing system in FIG. 1.

FIG. 3 is a cross-sectional view taken along the line A-A′ in FIG. 2.

FIG. 4 is a perspective view illustrating a process module of the substrate processing system in FIG. 1.

FIG. 5 is a perspective view illustrating a transfer robot of the substrate processing system in FIG. 1.

FIGS. 6A and 6B are plan views illustrating the transfer robot in FIG. 5.

FIGS. 7A to 7C are plan views illustrating operations of transferring a wafer in the substrate processing system in FIG. 1.

FIG. 8 is a plan view illustrating a substrate processing system according to one or more exemplary embodiments of the present inventive concept.

FIG. 9 is a cross-sectional view taken along the line B-B′ in FIG. 8.

FIG. 10 is a plan view illustrating a substrate processing system according to one or more exemplary embodiments of the present inventive concept.

FIG. 11 is a cross-sectional view taken along the line C-C′ in FIG. 10.

FIG. 12 is a cross-sectional view taken along the line D-D′ in FIG. 10.

FIG. 13 is a plan view illustrating operations of the first and second transfer robots in the substrate processing system in FIG. 10.

FIG. 14 is a plan view illustrating a substrate processing system according to one or more exemplary embodiments of the present inventive concept.

FIG. 15 is a cross-sectional view taken along the line E-E′ in FIG. 14.

FIG. 16 is a plan view illustrating a substrate processing system according to one or more exemplary embodiments of the present inventive concept.

FIG. 17 is a flowchart illustrating a substrate processing method according to one or more exemplary embodiments of the present inventive concept.

FIGS. 18 to 25 are cross-sectional views illustrating a method of manufacturing a semiconductor device according to one or more exemplary embodiments of the present inventive concept.

### DETAILED DESCRIPTION OF EXAMPLE EMBODIMENTS

Various exemplary embodiments of the present inventive concept will be described more fully hereinafter with reference to the accompanying drawings, in which some exemplary embodiments are shown. The present inventive concept may, however, be embodied in many different forms and should not be construed as limited to the exemplary embodiments set forth herein. In the drawings, the sizes and relative sizes of components or elements may be exaggerated for clarity of description.

It will be understood that when an element or layer is referred to as being “on,” “connected to” or “coupled to” another element or layer, it may be directly on, connected or coupled to the other element or layer or intervening elements or layers may be present. Like numerals may refer to like elements throughout the specification and drawings.

It will be understood that, although the terms first, second, etc. may be used herein to describe various elements, these elements should not be limited by these terms.

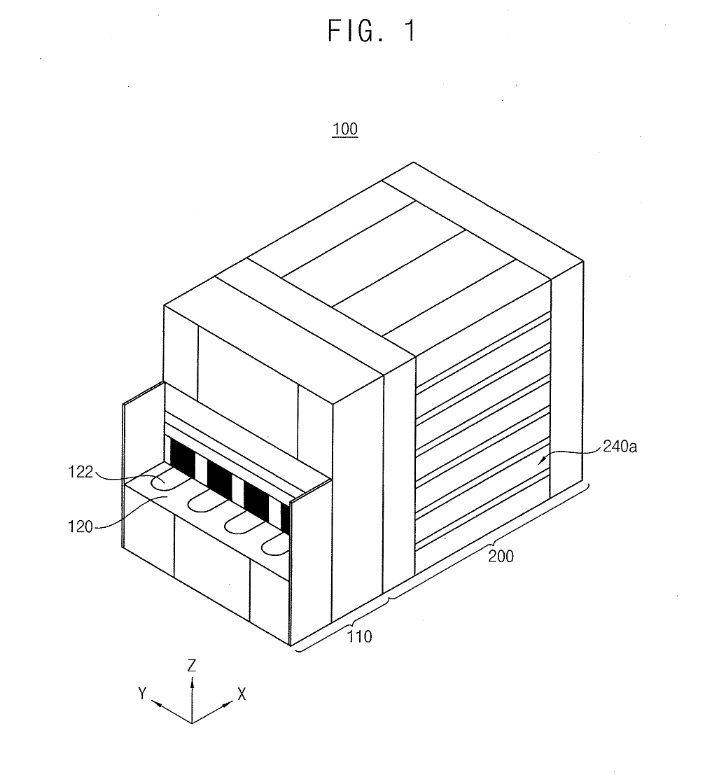

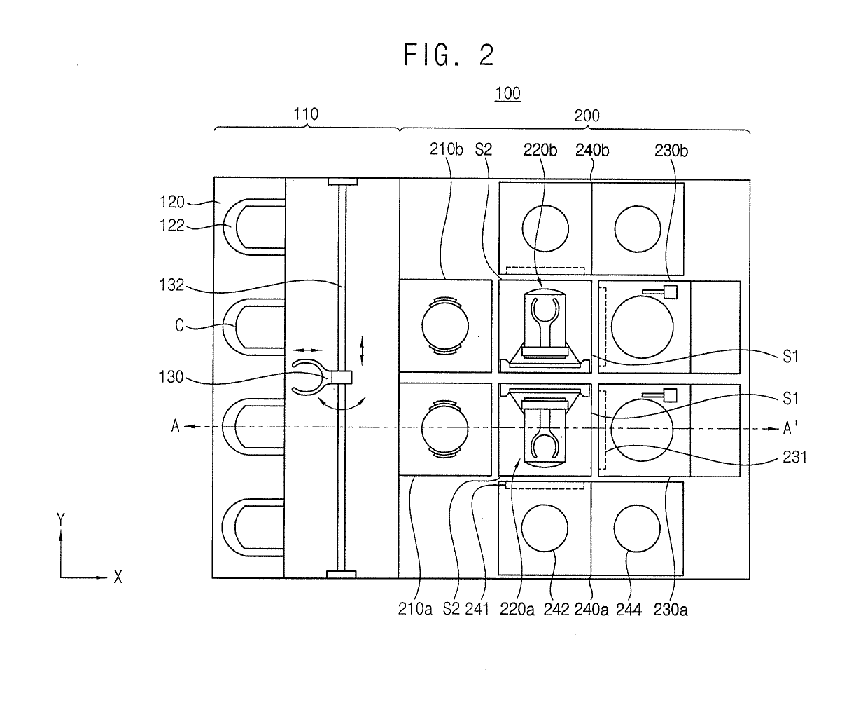

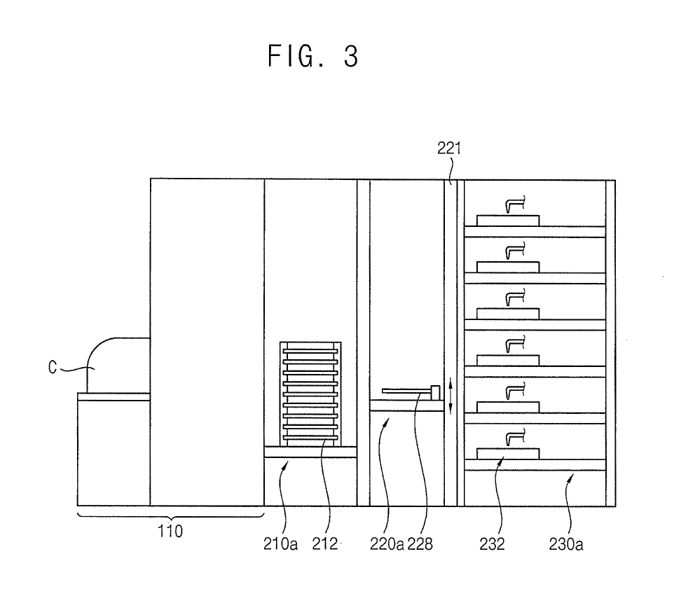

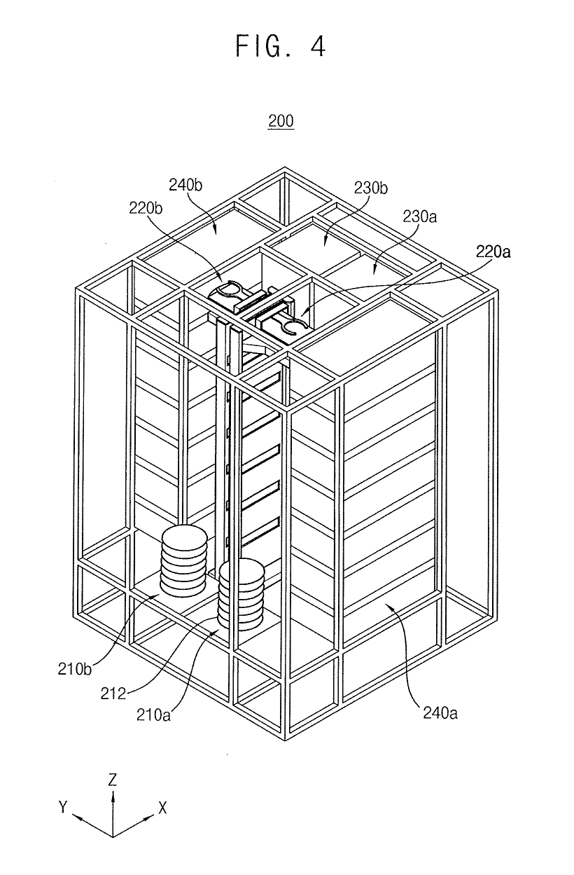

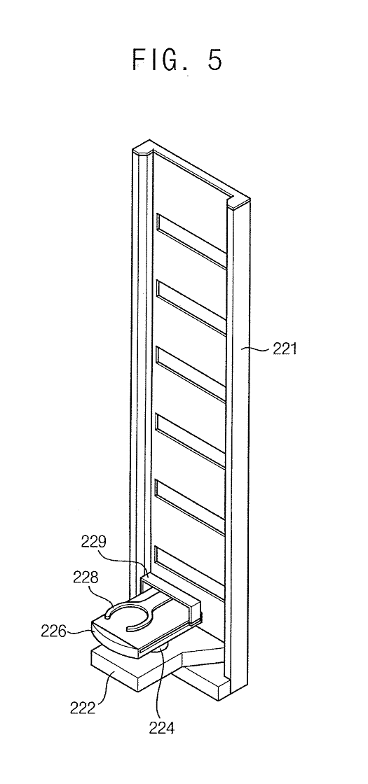

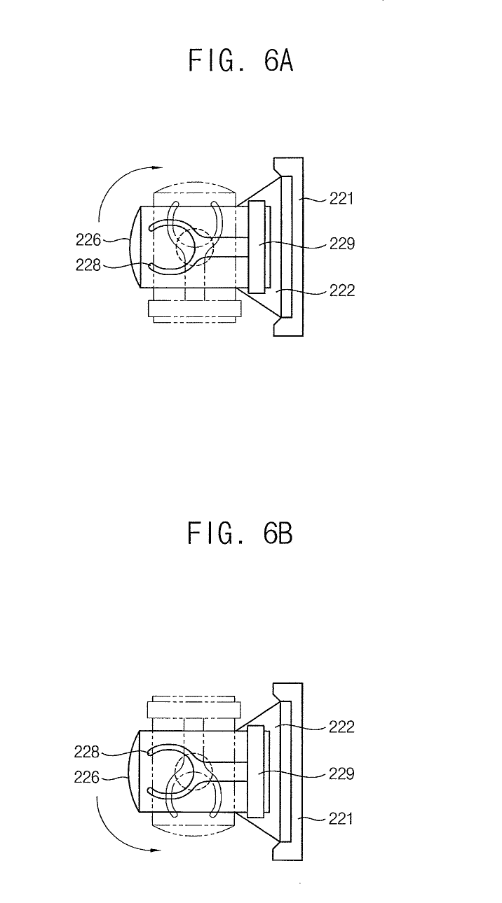

FIG. 1 is a perspective view illustrating a substrate processing system according to one or more exemplary embodiments of the present inventive concept. FIG. 2 is a plan view illustrating the substrate processing system in FIG. 1. FIG. 3 is a cross-sectional view taken along the line A-A′ in FIG. 2. FIG. 4 is a perspective view illustrating a process module of the substrate processing system in FIG. 1. FIG. 5 is a perspective view illustrating a transfer robot of the substrate processing system in FIG. 1. FIGS. 6A and 6B are plan views illustrating the transfer robot in FIG. 5. In all figures in this specification, a direction indicated by an arrow and a reverse direction thereof may refer to the same direction.

Referring to FIGS. 1, 2, 3, 4, 5, 6A and 6B, a substrate processing system 100 may include an index module 110 configured to load and unload wafers, and a process module 200 disposed adjacent to a first side of the index module 110 and configured to coat a mask layer on each of the wafers.

The process module 200 may be disposed along an X direction from the first side of the index module 110. The process module 200 may include first and second heat processing units 210a and 210b. The first and second heat processing units 210a and 210b may cool the wafers loaded/unloaded from/to the index module 110. The process module 200 may include first and second coating units 230a and 230b. The first and second coating units 230a and 230b may coat a mask layer on the wafer. The process module 200 may include first and second bake units 240a and 240b. The first and second bake units 240a and 240b may bake the mask layer coated on the wafer. The process module 200 may include a first transfer robot 220a. The first transfer robot 220a may transfer the wafer between the first heat processing unit 210a, the first coating unit 230a and the first bake unit 240a. The process module 200 may include a second transfer robot 220b. The second transfer robot may transfer the wafer between the second heat processing unit 210b, the second coating unit 230b and the second bake unit 240b.

According to one or more exemplary embodiments of the present inventive concept, the substrate processing system 100 may deposit a material layer such as a spin on hardmask (SOH) layer on the wafers. The SOH layer may be a mold layer (e.g., a sacrificial layer). The mold layer may be used to form a mask pattern in a double patterning process. The SOH layer may include an amorphous carbon layer (ACL), or a carbon-containing layer. For example, the SOH layer may be a hybrid SOH (H-SOH) layer.

Referring to FIG. 2, the index module 110 may include a rectangular cassette stage 120 and an index robot 130. A plurality of support plates 122 may be arranged along a longitudinal direction (e.g., a Y direction) on the cassette stage 120. A wafer carrier C carrying a plurality of wafers may be disposed on the support plate 122. The wafer carrier C may be a Front Opening Unified Pod (FOUP). The index robot 130 may be movable along a guide rail 132 in the Y direction to transfer the wafer between the carrier C and the process module 200. For example, the index robot 130 may transfer the wafers from the wafer carrier C to the first and second heat processing units 210a and 210b and may transfer the wafers from the first and second heat processing units 210a and 210b to the wafer carrier C.

The first and second heat processing units 210a and 210b may be disposed adjacent to the first side of the index module 110. The first heat processing unit 210a and the second heat processing unit 210b may be arranged along the first side of the index module 110 in the Y direction. The first and second heat processing units 210a and 210b may each include a plurality of heat processing plates 212. The heat processing plates 212 may be sequentially stacked in a vertical direction (e.g., a Z direction). For example, the heat processing plates 212 may be stacked in seven layers; however, exemplary embodiments of the present inventive concept are not limited thereto.

The heat processing plates 212 of the first and second heat processing units 210a and 210b may include a cooling plate. Thus, the first and second heat processing units 210a and 210b may perform a cooling process on the wafer on the heat processing plate 212 and the wafer may be cooled to a predetermined temperature. For example, the first and second heat processing units 210a and 210b may cool the wafer to about 23° C. The first and second heat processing units 210a and 210b may include a cooling pipe for cooling the cooling plate. The cooling pipe may extend in the cooling plate to circulate a cooling fluid therein.

The heat processing plates 212 of the first and second heat processing units 210a and 210b may include a heating plate. Thus, the first and second heat processing units 210a and 210b may perform a heating process on the wafer on the heat processing plate 212 and the wafer may be heated to a predetermined temperature. The first and second heat processing units 210a and 210b may include a heating wire for heating the heating plate.

The first and second transfer robots 220a and 220b may be disposed adjacent to the first and second heat processing units 210a and 201b. The first transfer robot 220a may be arranged to be spaced apart from the first heat processing unit 210a in the X direction and the second transfer robot 220b may be arranged to be spaced apart from the second heat processing unit 210b in the X direction. The first heat processing unit 210a may be arranged between the index module 110 and the first transfer robot 220a, and the second heat processing unit 210b may be arranged between the index module 110 and the second transfer robot 220b. The first heat processing unit 210a and the first transfer robot 220a may be arranged in line in the X direction from the first side of the index module 110. The second heat processing unit 210b and the second transfer robot 220b may be arranged in line in the X direction from the first side of the index module 110. The arrangement direction of the first heat processing unit 210a and the first transfer robot 220a may be parallel with the arrangement direction of the second heat processing unit 210b and the second transfer robot 220b.

The first and second transfer robots 220a and 220b may be movable along a vertical transfer path. The first transfer robot 220a and the second transfer robot 220b may have a similar or substantially a same configuration as each other. Referring to FIG. 5, the first and second transfer robots 220a and 220b may include a vertical transfer base 222 movable along a vertical guide rail 221 extending along the vertical transfer path. The first and second transfer robots 220a and 220b may include a horizontal transfer base 226 rotatably installed on the vertical transfer base 222 by a rotation mechanism. The first and second transfer robots 220a and 220b may include a transfer arm 228 movable forward and backward on the horizontal transfer base 226 by a carriage 229. The first and second transfer robots 220a and 220b may grip the wafer. The vertical guide rail 221 may include a plurality of opening slits which are spaced apart from each other and allow the transfer arm 228 to pass therethrough. Thus, the first and second transfer robots may transfer the wafer through the vertical movement and the rotation movement at respective installed positions. The first and second transfer robots 220a and 220b may include a transfer robot of a vertical transfer type movable along the vertical guide rail. That is, the first and second transfer robots 220a and 220b need not travel along a track extending in a horizontal direction (e.g., the X or Y directions) such as a horizontal guide rail.

The first coating unit 230a may face the index module 110 with the first heat processing unit 210a disposed between the index module 110 and the first coating unit 230a. The second coating unit 230b may face the index module 110 with the second heat processing unit 210b disposed between the index module 110 and the second coating unit 230b. The first coating unit 230a may be disposed adjacent to a first side S1 of the first transfer robot 220a in the X direction. The second coating unit 230b may be disposed adjacent to a first side S1 of the second transfer robot 220b in the X direction. The first side S1 of the first transfer robot 220a may be substantially parallel with the Y direction. The first side S1 of the second transfer robot 220b may be substantially parallel with the Y direction.

The first coating unit 230a may be arranged from the first transfer robot 220a in the first direction, and the second coating unit 230b may be arranged from the second transfer robot 220b in the first direction. The first direction may be a direction parallel with the X direction. The first heat processing unit 210a, the first transfer robot 220a and the first coating unit 230a may be arranged substantially in line in the X direction from the first side of the index module 110. The second heat processing unit 210b, the second transfer robot 220b and the second coating unit 230b may be arranged substantially in line in the X direction from the first side of the index module 110.

Gates 231 allowing passage of the wafer may be provided in first sides of coating devices 232 of the first and second coating units 230a and 230b, respectively. The first and second coating units 230a and 230b may be arranged with the first sides of the coating devices 232 crossing the first direction. For example, the first and second coating units 230a and 230b may be arranged with the first sides of the coating devices extending in a direction (e.g., the Y direction) substantially perpendicular to the first direction (e.g., the X direction). Thus, the first and second transfer robots 220a and 220b may rotate to face toward the first direction and to transfer the wafers from the first and second heat processing units 210a and 210b to the first and second coating units 230a and 230b, respectively.

The first and second coating units 230a and 230b may each include a plurality of the coating devices 232 sequentially stacked in the vertical direction (e.g., the Z direction). For example, the coating devices 232 may be stacked in six layers; however, exemplary embodiments of the present inventive concept are not limited thereto.

The coating device 232 may coat a desired layer on the wafer on a support plate. For example, the coating device 232 may include a spin coater. The spin coater may include the support plate for supporting and rotating the wafer and a nozzle unit for spraying a coating material on the wafer on the support plate. The coating material may include a chemical used for coating the SOH layer.

The first bake unit 240a may be disposed adjacent to a second side S2 of the first transfer robot 220a in the Y direction. The second bake unit 240b may be disposed adjacent to a second side S2 of the second transfer robot 220b in the Y direction. The second side S2 of the first transfer robot 220a may be adjacent to the first side S1 of the first transfer robot 220a. The second side S2 of the second transfer robot 220b may be adjacent to the first side S2 of the second transfer robot 220b. The second side S2 of the first transfer robot 220a may be substantially parallel with the X direction. The second side S2 of the second transfer robot 220b may be substantially parallel with the X direction.

The first bake unit 240a may be disposed adjacent to the first transfer robot 220a in a second direction different from the first direction, and the second bake unit 240b may be disposed adjacent to the second transfer robot 220b in the second direction different from the first direction. The second direction may be parallel with the Y direction. Gates 241 allowing passage of the wafer may be provided in first sides of each of the first and second bake units 240a and 240b. The first and second bake units 240a and 240b may be arranged with the first sides of the first and second bake units 240a and 240b crossing the second direction. For example, the first and second bake units 240a and 240b may be arranged with the first sides of the first and second bake units 240a and 240b extending in a direction (e.g., the X direction) substantially perpendicular to the second direction. Thus, the first and second transfer robots 220a and 220b may rotate to face toward the second direction and to transfer the wafers from the first and second coating units 230a and 230b to the first and second bake units 240a and 240b.

The first and second bake units 240a and 240b may include a plurality of bake devices sequentially stacked in the vertical direction (e.g., the Z direction). For example, the bake devices may be stacked in seven layers; however, exemplary embodiments of the present inventive concept are not limited thereto.

The bake device may include a heat processing plate 242 for pre-heating the wafer to a desired temperature and a heater 244 for heating the wafer. The heater 244 may heat the wafer to about 400° C. The heat processing plate 242 may pre-heat or pre-cool the wafer to a desired temperature before transferring the wafer to the heater 244.

The first heat processing unit 210a, the first transfer robot 220a and the first coating unit 230a may be arranged in a middle region of the process module 200, and the first bake unit 240a may be arranged in a peripheral region of the process module 200. The second heat processing unit 210b, the second transfer robot 220b and the second coating unit 230b may be arranged in a middle region of the process module 200, and the second bake unit 240b may be arranged in a peripheral region of the process module 200. The first bake unit 240a and the second bake unit 240b may be arranged in the Y direction to face each other with the first and second transfer robots 220a and 220b disposed between the first bake unit 240a and the second bake unit 240b.

The first transfer robot 220a may transfer the wafer between the first heat processing unit 210a, the first coating unit 230a and the first bake unit 240a through the vertical movement and the rotation movement at the installed position. The second transfer robot 220b may transfer the wafer between the second heat processing unit 210b, the second coating unit 230b and the second bake unit 240b through the vertical movement and the rotation movement at the installed position.

The first coating unit 230a, the first bake unit 240a and the first heat processing unit 210a may be disposed adjacent to the first, second and third sides of the first transfer robot 220a, respectively. The first heat processing unit 210a, the first coating unit 230a and the first bake unit 240a may be disposed radially outwardly with respect to the first transfer robot 220a. The first heat processing unit 210a, the first coating unit 230a and the first bake unit 240a may be disposed around the first transfer robot 220a and may share the first transfer robot 220a. Thus, the wafer may be transferred between the first coating unit 230a, the first bake unit 240a and the first heat processing unit 210a by the first transfer robot 220a.

The second coating unit 230b, the second bake unit 240b and the second heat processing unit 210b may be disposed adjacent to the first, second and third sides of the second transfer robot 220b, respectively. The second heat processing unit 210b, the second coating unit 230b and the second bake unit 240b may be disposed radially outwardly with respect to the second transfer robot 220b. The second heat processing unit 210b, the second coating unit 230b and the second bake unit 240b may be disposed around the second transfer robot 220b and may share the second transfer robot 220b. Thus, the wafer may be transferred between the second coating unit 230b, the second bake unit 240b and the second heat processing unit 210b by the first transfer robot 220a.

Referring to FIGS. 6A and 6B, the transfer arm 228 may rotate clockwise or counterclockwise by moving a rotation shaft 224, and the transfer arm 228 may move forward and backward by moving the carriage 229 to load and unload the wafer.

A method of transferring a wafer using the first and second transfer robots in FIG. 1 will be described below in more detail.

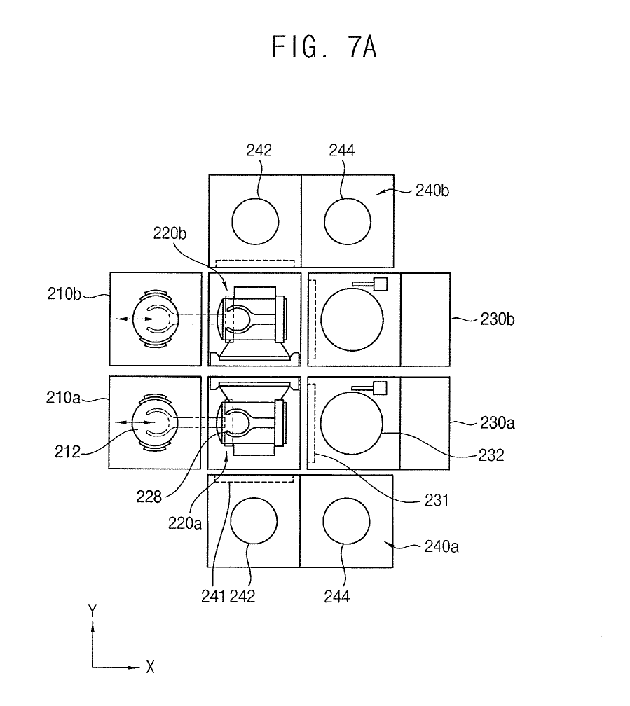

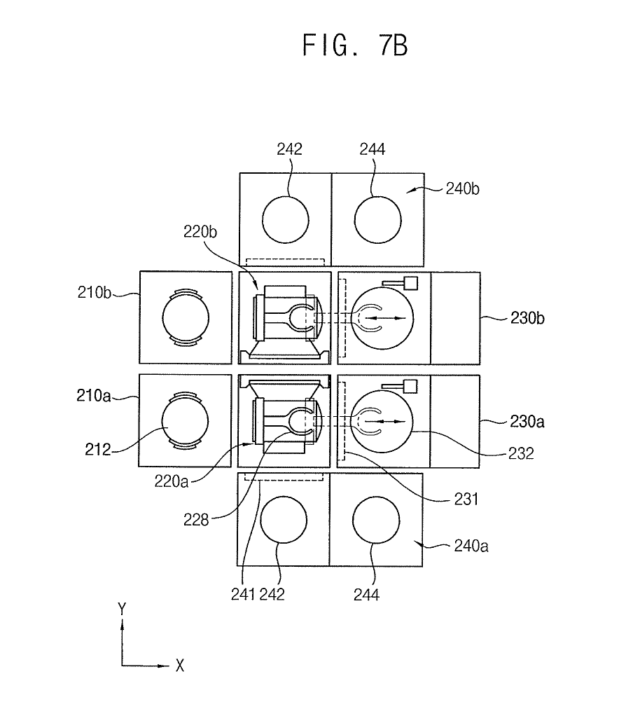

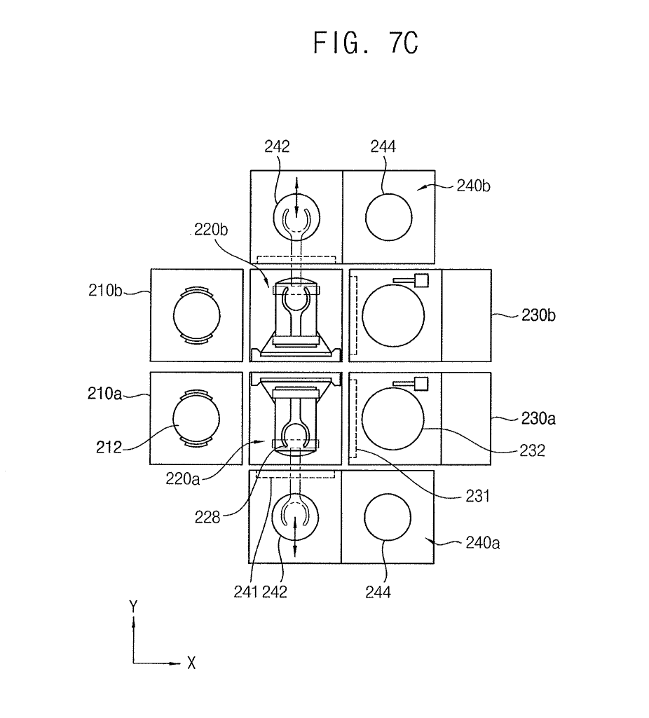

FIGS. 7A to 7C are plan views illustrating operations of transferring a wafer in the substrate processing system in FIG. 1.

Referring to FIGS. 7A and 7B, wafers may be transferred from the wafer cassette C supported in the index module 110 to the first and second heat processing units 210a and 210b, and then, the wafers may be loaded into the first and second coating units 230a and 230b from the first and second heat processing units 210a and 210b.

The wafers may be selectively drawn out from the wafer cassette C by the index robot 130 and then sequentially transferred to the heat processing plates 212 of the first and second heat processing units 210a and 210b. The heat processing plates 212 of the first and second heat processing units 210a and 210b may serve as a buffer plate for temporarily supporting the wafer before processing of the wafer and after processing of the wafer.

The transfer arm 228 of the first transfer robot 220a may move forward and access the wafer on the heat processing plate 212 of the first heat processing unit 210a and move backward and draw out the wafer from the first heat processing unit 210a. The transfer arm 228 of the first transfer robot 220a may rotate to face toward the first direction (e.g., the X direction), and then may transfer the wafer to the first coating unit 230a. The transfer arm 228 of the second transfer robot 220b may move forward and access the wafer on the heat processing plate 212 of the second heat processing unit 210b and move backward and draw out the wafer from the second heat processing unit 210b. The transfer arm 228 of the second transfer robot 220b may rotate to face toward the first direction (e.g., the X direction), and then may transfer the wafer to the second coating unit 230b.

The wafers may be loaded into the spin coaters of the first and second coating units 230a and 230b. When the wafer is rotated at a predetermined speed, a coating material may be discharged on the wafer and an SOH layer may be coated on the wafer to have a desired thickness. Thus, the thickness of the layer coated on the wafer may be increased proportional to the amount of the discharged coating material and may be increased inversely proportional to the rotation speed of the support plate.

Referring to FIGS. 7B and 7C, after performing the spin coating processes, the wafers may be transferred from the first and second coating units 230a and 230b to the first and second bake units 240a and 240b, respectively.

The transfer arm 228 of the first transfer robot 220a may move forward and access the wafer on the support plate of the first coating unit 230a and move backward and draw out the wafer from the first coating unit 230a. The transfer arm 228 of the first transfer robot 220a may rotate to face toward the second direction (e.g., the Y direction) substantially perpendicular to the first direction, and then may transfer the wafer to the heat processing plate 242 of the first bake unit 240a. The transfer arm 228 of the second transfer robot 220b may move forward and access the wafer on the support plate of the second coating unit 230b and move backward and draw out the wafer from the second coating unit 230b. The transfer arm 228 of the second transfer robot 220b may rotate to face toward the second direction (e.g., the Y direction) substantially perpendicular to the first direction, and then may transfer the wafer to the heat processing plate 242 of the second bake unit 240b. After the wafer on the heat processing plate 242 is transferred to the heater 244 by a transfer mechanism of the bake device, the heater 244 may heat the wafer to perform a bake process on the coated layer.

After performing the bake process, the wafers may be unloaded from the first and second bake units 240a and 240b to the index module 100 through the first and second heat processing units 210a and 210b, respectively.

The substrate processing system may include dual transfer robots movable upward and downward along the vertical transfer path at respective installed positions. The transfer robots may transfer the wafer between the coating unit and the bake unit through the rotation movement and the vertical movement without travelling along X direction.

Thus, relatively high productivity of about 300 UPH (units per hour) or more may be achieved while maintaining the transfer robot to operate at a relatively low speed. Since the operating speed is decreased or maintained to a relatively low speed, load on the transfer robot may be reduced, particles may be reduced prevented from being generated in the equipment, and a lifespan of the transfer robot may be increased.

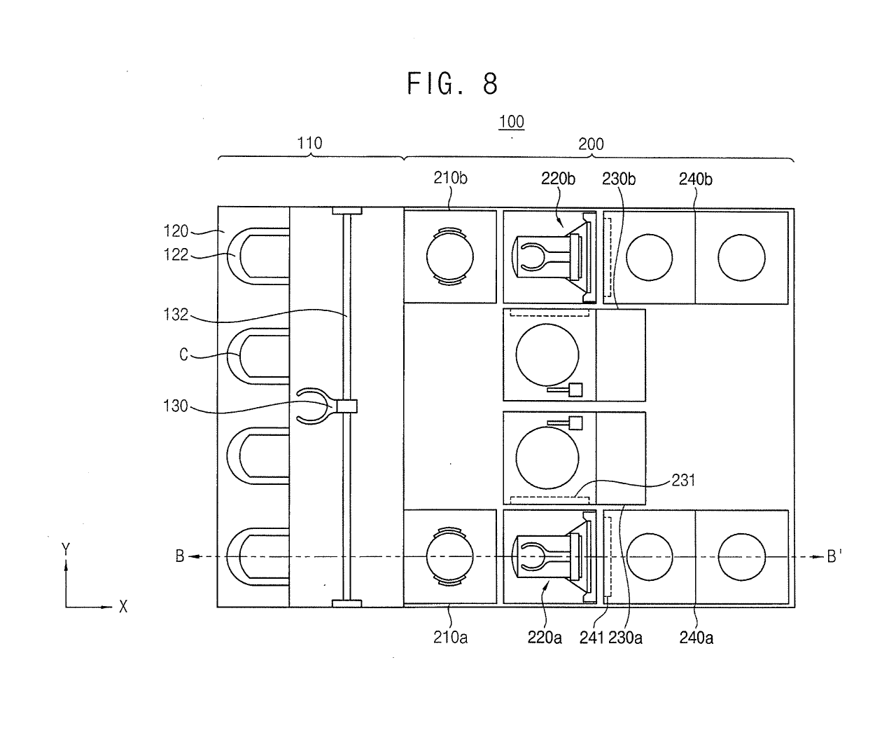

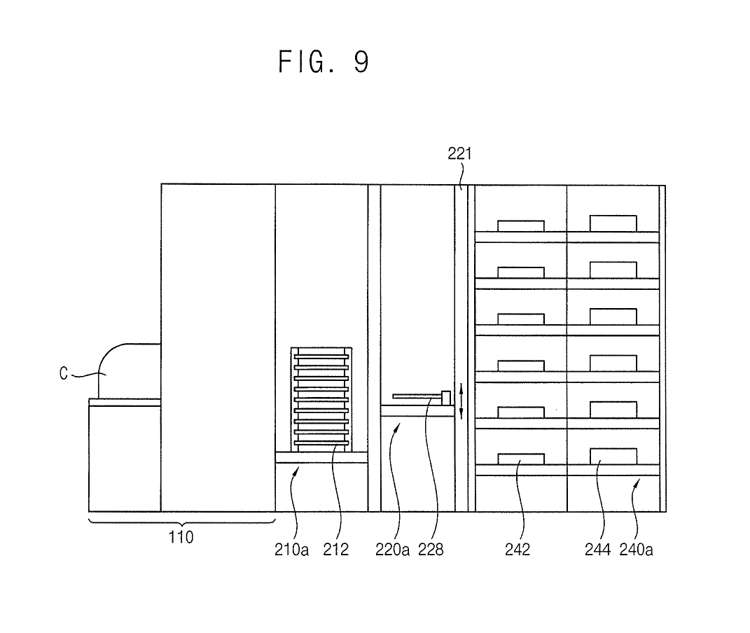

FIG. 8 is a plan view illustrating a substrate processing system according to one or more exemplary embodiments of the present inventive concept. FIG. 9 is a cross-sectional view taken along the line B-B′ in FIG. 8. The substrate processing system may be substantially the same as or similar to the substrate processing system described with reference to FIGS. 1 to 5, 6A and 6B, except for arrangements of first and second coating units and first and second bake units. Thus, the same reference numerals may be used to refer to the same or like elements and duplicative descriptions may be omitted.

Referring to FIGS. 8 and 9, first and second heat processing units 210a and 210b may be disposed adjacent to a first side of the index module 110. The first and second heat processing units 210a and 210b may be arranged in opposite peripheral regions of the process module 200 to face each other.

First and second transfer robots 220a and 220b may be disposed adjacent to the first and second heat processing units 210a and 210b, respectively. The first transfer robot 220a may be spaced apart from the first heat processing unit 210a in the X direction, and the second transfer robot 220b may be spaced apart from the second heat processing unit 210b in the X direction. The first heat processing unit 210a may be arranged between the index module 110 and the first transfer robot 220a, and the second heat processing unit 210b may be arranged between the index module 110 and the second transfer robot 220b.

The first bake unit 240a may face the index module 110 with the first heat processing unit 210a disposed between the first bake unit 240a and the index module 110. The second bake unit 240b may face the index module 110 with the second heat processing unit 210b disposed between the second bake unit 240b and the index module 110.

According to one or more exemplary embodiments of the present inventive concept, the first bake unit 240a may be disposed adjacent to the first side S1 of the first transfer robot 220a in the X direction. The second bake unit 240b may be disposed adjacent to the first side S1 of the second transfer robot 220b in the X direction. The first side S1 of the first transfer robot 220a may be substantially parallel with the Y direction. The first side S1 of the second transfer robot 220b may be substantially parallel with the Y direction.

The first bake unit 240a may be adjacent to the first transfer robot 220a in a first direction, and the second bake unit 240b may be adjacent to the second transfer robot 220b in the first direction. The first direction may be a direction substantially parallel with the X direction. The first heat processing unit 210a, the first transfer robot 220a and the first bake unit 240a may be arranged in line in the X direction from the first side of the index module 110. The second heat processing unit 210b, the second transfer robot 220b and the second bake unit 240b may be arranged in line in the X direction from the first side of the index module 110.

Gates 241 allowing passage of the wafer may be provided in first sides of each of the first and second bake units 240a and 240b. The first and second bake units 240a and 240b may be arranged with their first sides crossing the first direction. For example, the first and second bake units 240a and 240b may be arranged their first sides extending in a direction (e.g., the Y direction) substantially perpendicular to the first direction.

The first coating unit 230a may be disposed adjacent to the second side S2 of the first transfer robot 220a in the Y direction. The second coating unit 230b may be disposed adjacent to the second side S2 of the second transfer robot 220b in the Y direction. The second side S2 of the first transfer robot 220a may be adjacent to the first side S1 of the first transfer robot 220a. The second side S2 of the second transfer robot 220b may be adjacent to the first side S2 of the second transfer robot 220b. The second side S2 of the first transfer robot 220a may be substantially parallel with the X direction. The second side S2 of the second transfer robot 220b may be substantially parallel with the X direction.

The first coating unit 230a may be adjacent to the first transfer robot 220a in a second direction different from the first direction, and the second coating unit 230b may be adjacent to the second transfer robot 220b in the second direction different from the first direction. The second direction may be substantially parallel with the Y direction.

Gates 231 allowing passage of the wafer may be provided in first sides of each of the first and second coating units 230a and 230b. The first and second coating units 230a and 230b may be arranged with their first sides crossing the second direction. For example, the first and second coating units 230a and 230b may be arranged with their first sides extending in a direction (e.g., the X direction) substantially perpendicular to the second direction. The first heat processing unit 210a, the first transfer robot 220a and the first bake unit 240a may be arranged in the peripheral region of the process module 200, and the first coating unit 230a may be arranged in the middle region of the process module 200. The second heat processing unit 210b, the second transfer robot 220b and the second bake unit 240b may be arranged in the peripheral region of the process module 200, and the second coating unit 230b may be arranged in the middle region of the process module 200. The first transfer robot 220a and the second transfer robot 220b may be arranged in the Y direction to face each other with the first and second coating units 230a and 230b disposed between the first transfer robot 220a and the second transfer unit 220b. Since the first and second transfer robots 220a and 220b are arranged in the peripheral regions of the process module 200, maintenance of the transfer robots may be more easily performed.

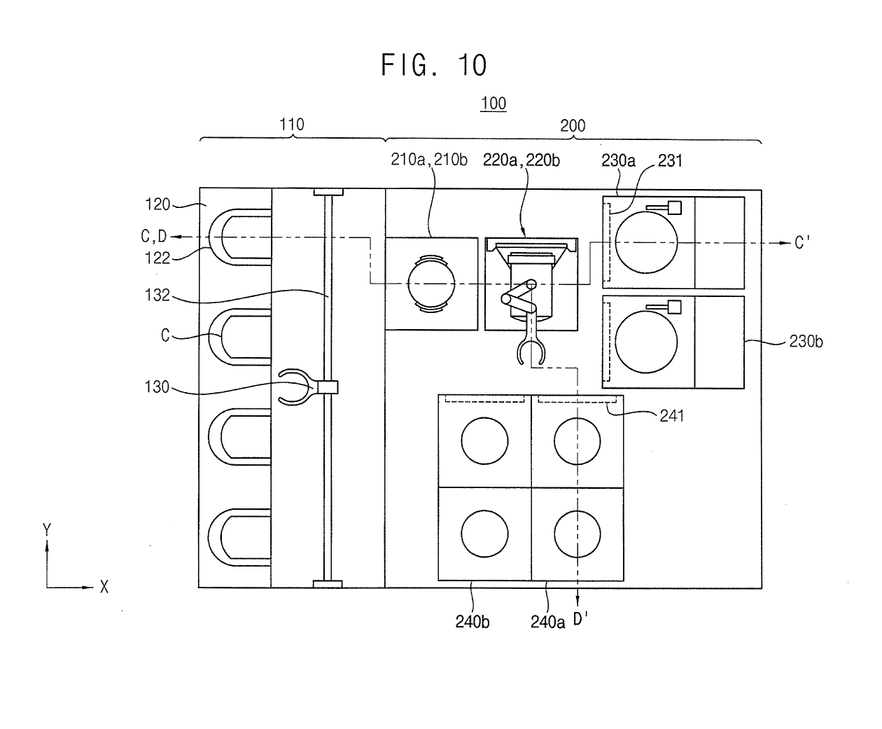

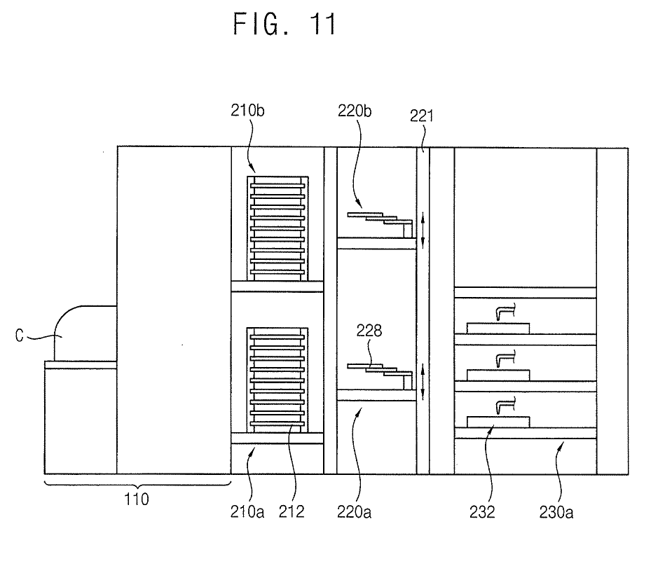

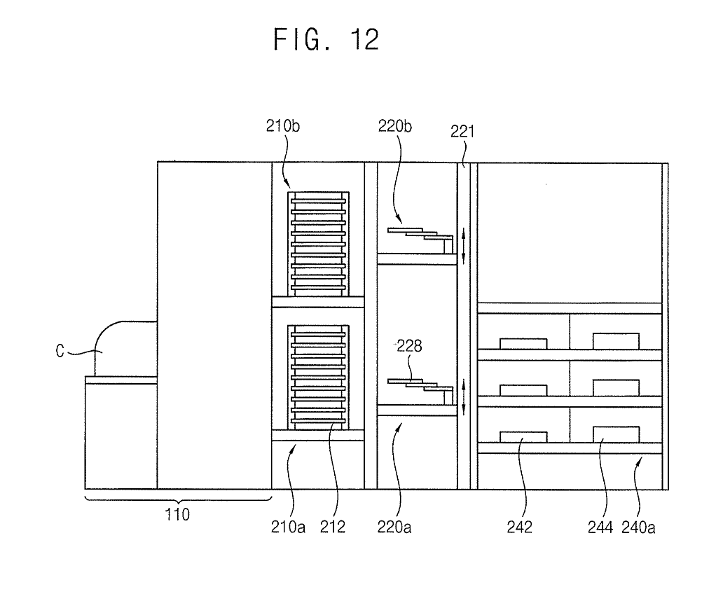

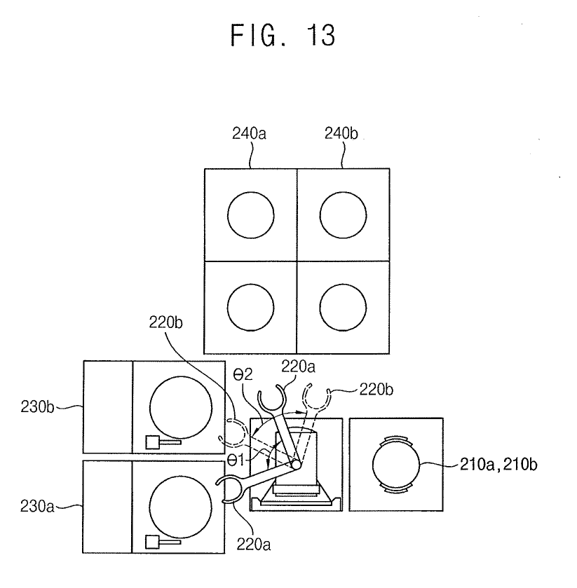

FIG. 10 is a plan view illustrating a substrate processing system according to one or more exemplary embodiments of the present inventive concept. FIG. 11 is a cross-sectional view taken along the line C-C′ in FIG. 10. FIG. 12 is a cross-sectional view taken along the line D-D′ in FIG. 10. FIG. 13 is a plan view illustrating operations of the first and second transfer robots in the substrate processing system in FIG. 10. The substrate processing system may be substantially the same as or similar to the substrate processing system described above with reference to FIGS. 1 to 5, 6A and 6B, except for arrangements of first and second heat processing units, first and second transfer robots, first and second coating units, and first and second bake units. Thus, the same reference numerals may refer to the same or like elements and duplicative descriptions may be omitted.

Referring to FIGS. 10 to 13, first and second heat processing units 210a and 210b may be disposed adjacent to a first side of the index module 110 and may be stacked on each other in a vertical direction. First and second transfer robots 220a and 220b may be stacked on each other in the vertical direction corresponding to the first and second heat processing units 210a and 210b. When viewed in the plan view, the first heat processing unit 210a and the first transfer robot 220a may be arranged in line in the X direction from the first side of the index module 110. The second heat processing unit 210b and the second transfer robot 220b may be arranged in line in the X direction from the first side of the index module 110.

The first transfer robot 220a may be movable along the vertical guide rail 221 in the vertical direction and may transfer a wafer to/from cooling plates 212 of the first heat processing unit 210a. The second transfer robot 220b may be movable along the vertical guide rail 221 in the vertical direction and may transfer a wafer to/from heat processing plates 212 of the first heat processing unit 210a.

According to one or more exemplary embodiments of the present inventive concept, the first coating unit 230a may be disposed adjacent to a first side of the first transfer robot 220a. The first bake unit 240a may be disposed adjacent to a second side of the first transfer robot 220a. The second side of the first transfer robot 220a may be adjacent to the first side of the first transfer robot 220a. The second coating unit 230b may be disposed adjacent to a first side of the second transfer robot 220a. The second bake unit 230b may be disposed adjacent to a second side of the second transfer robot 220b. The second side of the second transfer robot 220b may be adjacent to the first side of the second transfer robot 220b.

In a plan view, the first coating unit 230a may be adjacent to and offset from the first transfer robot 220a along the first direction, and the second coating unit 230b may be adjacent to and offset from the second transfer robot 220b along the first direction. In a plan view, the first bake unit 240a may be adjacent to and offset from the first transfer robot 220a along a second direction different from the first direction, and the second bake unit 240b may be adjacent to and offset from the second transfer robot 220b along the second direction. For example, the second direction may be substantially perpendicular to the first direction.

Gates 231 allowing passage of the wafer may be provided in first sides of coating devices of the first coating unit 230a. The first coating unit 230a may be arranged with its first side crossing the first direction. Gates 231 allowing passage of the wafer may be provided in first sides of coating devices of the second coating unit 230b. The second coating unit 230b may be arranged with its first side crossing the third direction. For example, the first and second coating units may be arranged with their first sides extending in Y direction.

Gates 241 allowing passage of the wafer may be provided in first sides of bake devices of the first bake unit 240a. The first bake unit 240a may be arranged with its first side crossing the second direction. Gates 241 allowing passage of the wafer may be provided in first sides of bake devices of the second bake unit 240b. The second bake unit 240b may be arranged with its first side crossing the first direction. For example, the first and second bake units may be arranged with their first sides extending in the X direction. The first transfer robot 220a may transfer the wafer between the first heat processing unit 210a, the first coating unit 230a and the first bake unit 240a. The second transfer robot 220b may transfer the wafer between the second heat processing unit 210b, the second coating unit 230b and the second bake unit 240b.

Referring to FIG. 13, the transfer arm 228 of the first transfer robot 220a may rotate by a first rotation angle θ1 to transfer the wafer between the first coating unit 230a and the first bake unit 240a, and the transfer arm 228 of the second transfer robot 220b may rotate by a second rotation angle θ2 to transfer the wafer between the second coating unit 230b and the second bake unit 240b. For example, the first rotation angle θ1 may be substantially the same as the second rotation angle θ2. The first rotation angle θ1 and the second rotation angle θ2 may each be about 90 degrees. The first and second transfer robots may include a horizontally articulating robot. For example, the first and second transfer robots may include a Selective Compliance Assembly Robot (SCARA).

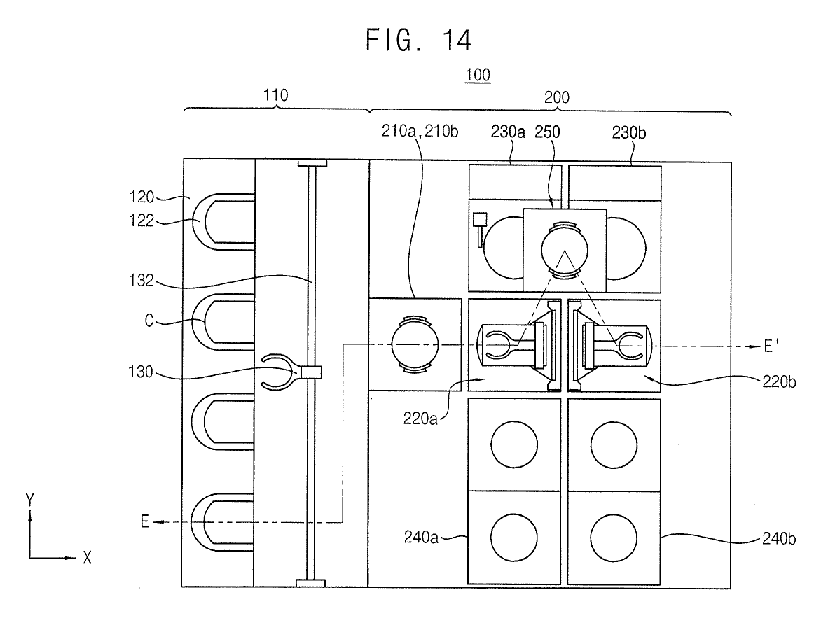

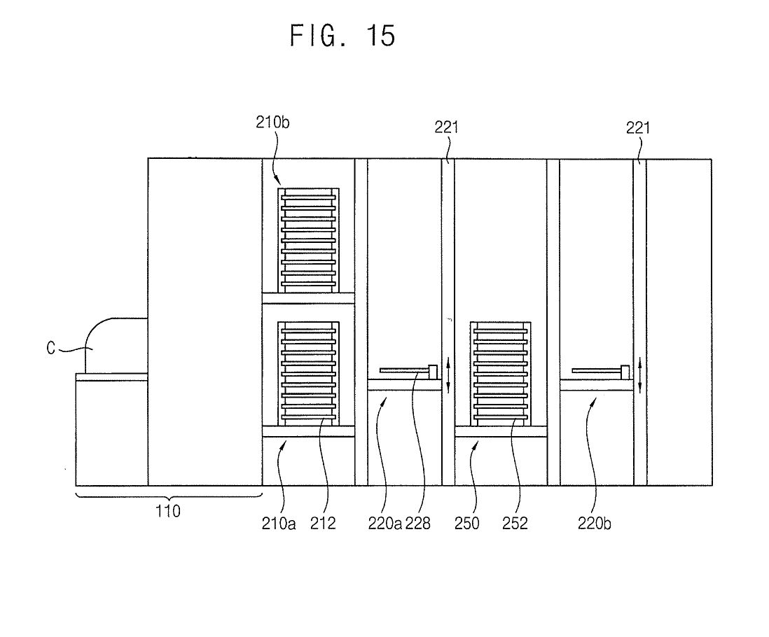

FIG. 14 is a plan view illustrating a substrate processing system according to one or more exemplary embodiments of the present inventive concept. FIG. 15 is a cross-sectional view taken along the line E-E′ in FIG. 14. The substrate processing system may be substantially the same as or similar to the substrate processing system described above with reference to FIGS. 1 to 5, 6A and 6B, except for arrangements of first and second heat processing units, first and second transfer robots, first and second coating units, and first and second bake units. Thus, the same reference numerals may refer to the same or like elements and duplicative descriptions may be omitted.

Referring to FIGS. 14 and 15, first and second heat processing units 210a and 210b may be disposed adjacent to a first side of the index module 110 and may be stacked on each other in a vertical direction. First and second transfer robots 220a and 220b may be arranged in line in the X direction from the first side of the index module 110. When viewed in the plan view, the first and second heat processing units 210a and 210b, the first transfer robot 220a and the second transfer robot 220b may be arranged in line in the X direction from the first side of the index module 110.

According to one or more exemplary embodiments of the present inventive concept, the substrate processing system 100 may include a buffer unit 250. The buffer unit 250 may be disposed between the first and second transfer robots 220a and 220b and may temporarily support a wafer to transfer the wafer between the first and second transfer robots 220a and 220b. The buffer unit 250 may include a plurality of buffer plates 252 sequentially stacked in a vertical direction and each supporting a wafer.

The first coating unit 230a may be disposed adjacent to a first side of the first transfer robot 220a. The first bake unit 240a may be disposed adjacent to a second side opposite to the first side of the first transfer robot 220a. The second coating unit 230b may be disposed adjacent to a first side of the second transfer robot 220b. The second bake unit 240b may be disposed adjacent to a second side opposite to the first side of the second transfer robot 220b.

The first transfer robot 220a may be movable along the vertical guide rail 221 in the vertical direction and may transfer some of wafers from cooling plates 212 of the first and second heat processing units 210a and 210b stacked on each other to the buffer plates 252 of the buffer unit 250. The second transfer robot 220b may transfer the wafers from the buffer plates 252 of the buffer unit 250 to the second coating units 230b.

The first transfer robot 220a may transfer the wafer between the first and second heat processing units 210a and 210b, the first coating unit 230a, the first bake unit 240a and the buffer unit 250. The second transfer robot 220b may transfer the wafer between the second coating unit 230b, the second bake unit 240b and the buffer unit 250.

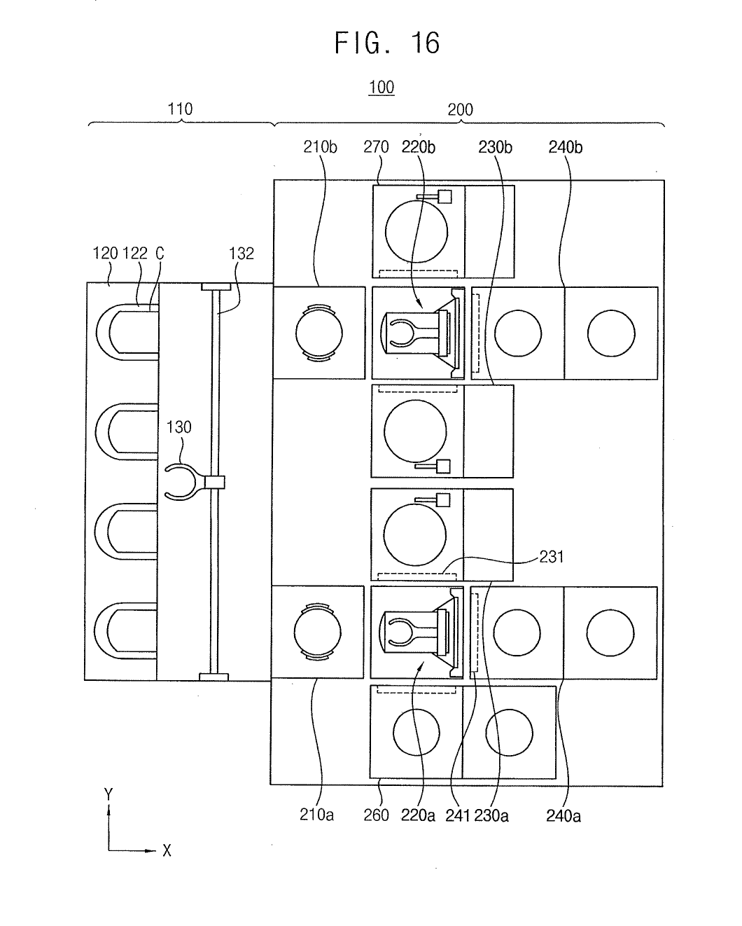

FIG. 16 is a plan view illustrating a substrate processing system according to one or more exemplary embodiments of the present inventive concept. The substrate processing system may be substantially the same as or similar to the substrate processing system as described with reference to FIGS. 8 and 9, except for arrangements of first and second coating units and first and second bake units. Thus, same reference numerals will be used to refer to the same or like elements and any further repetitive explanation concerning the above elements will be omitted.

Referring to FIG. 16, the substrate processing system 100 may include a third bake unit 260 and a third coating unit 270 disposed adjacent to third sides of first and second transfer robots 220a and 220b, respectively.

According to one or more exemplary embodiments of the present inventive concept, the first transfer robot 220a may be spaced apart from the first heat processing unit 210a in X direction, and the second transfer robot 220b may be spaced apart from the second heat processing unit 210b in the X direction. The first coating unit 230a may be spaced apart from the first transfer robot 220a in the Y direction, and the second coating unit 230b may be spaced apart from the second transfer robot 220b in the Y direction. The first bake unit 240a may be spaced apart from the first transfer robot 220a in the X direction, and the second bake unit 240b may be spaced apart from the second transfer robot 220b in the X direction.

The first coating unit 230a may be disposed adjacent to a first side of the first transfer robot 220a in the Y direction. The second coating unit 230b may be disposed adjacent to a first side of the second transfer robot 220b in the Y direction. The first side of the first transfer robot 220a may be substantially parallel with the X direction. The first side of the second transfer robot 220b may be substantially parallel with the X direction.

The first bake unit 240a may be disposed adjacent to a second side of the first transfer robot 220a in the X direction. The second bake unit 240b may be disposed adjacent to a second side of the second transfer robot 220b in the X direction. The second side of the first transfer robot 220a may be adjacent to the first side of the first transfer robot 220a. The second side of the second transfer robot 220b may be adjacent to the first side of the second transfer robot 220b. The second side of the first transfer robot 220a may be substantially parallel with the Y direction. The second side of the second transfer robot 220b may be substantially parallel with the Y direction.

According to one or more exemplary embodiments of the present inventive concept, the third bake unit 260 may be disposed adjacent to the third side of the first transfer robot 220a. The third side of the first transfer robot 220a may be opposite to the first side of the first transfer robot 220a. The third coating unit 270 may be disposed adjacent to the third side of the second transfer robot 220b. The third side of the second transfer robot 220b may be opposite to the first side of the second transfer robot 220b. The third side of the first transfer robot 220a may be substantially parallel with the X direction. The third side of the second transfer robot 220b may be substantially parallel with the X direction.

The first heat processing unit 210a, the first coating unit 230a, the first bake unit 240a and the third bake unit 260 may be disposed adjacent to the fourth, first, second and third sides of the first transfer robot 220a, respectively. The first heat processing unit 210a, the first coating unit 230a, the first bake unit 240a and the third bake unit 260 may be disposed radially outward with respect to the first transfer robot 220a. The first heat processing unit 210a, the first coating unit 230a, the first bake unit 240a and the third bake unit 260 may be disposed around the first transfer robot 220a and may share the first transfer robot 220a. Thus, the wafer may be transferred between the first heat processing unit 210a, the first coating unit 230a, the first bake unit 240a and the third bake unit 260 by the first transfer robot 220a.

The second heat processing unit 210b, the second coating unit 230b, the second bake unit 240b and the third coating unit 270 may be disposed adjacent to the fourth, first, second and third sides of the second transfer robot 220b. The second heat processing unit 210b, the second coating unit 230b, the second bake unit 240b and the third coating unit 270 may be disposed radially outward with respect to the second transfer robot 220b. The second heat processing unit 210b, the second coating unit 230b, the second bake unit 240b and the third coating unit 270 may be disposed around the second transfer robot 220b and may share the second transfer robot 220b. Thus, the wafer may be transferred between the second heat processing unit 210b, the second coating unit 230b, the second bake unit 240b and the third coating unit 270 by the second transfer robot 220b.

The third bake unit 260 and the third coating unit 270 may be disposed in opposite peripheral regions of the process module 200. Alternatively, two additional coating units may be disposed in the opposite peripheral regions of the process module 200, or two additional bake units may be disposed in the opposite peripheral regions of the process module 200.

The coating devices and the bake devices sequentially stacked may be disposed in different sides of the transfer robot around the transfer robot. Thus, a number of wafers may be processed in a limited equipment space.

A method of processing wafers using the substrate processing system according to one or more exemplary embodiments of the present inventive concept will be described below in more detail.

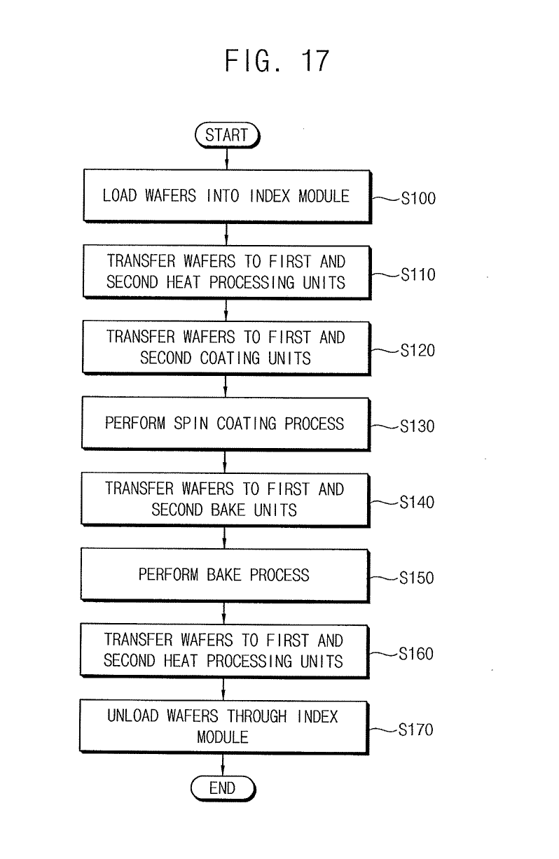

FIG. 17 is a flowchart illustrating a substrate processing method according to one or more exemplary embodiments of the present inventive concept.

Referring to FIGS. 2, 3 and 17, wafers may be loaded into an index module (S100). For example, the wafers may be loaded onto a cassette stage 120 of an index module 110. The wafers may be transferred to first and second heat processing units 210a and 210b (S110).

According to one or more exemplary embodiments of the present inventive concept, the wafer carrier C receiving the wafers having an etch target layer therein may be loaded into the index module 110. The index robot 130 may transfer sequentially the wafers from the wafer carrier C to the first and second heat processing units 210a and 210b disposed in a first side of the index module 110.

The wafers may be transferred to heat processing plates 212 of the first and second heat processing units 210a and 210b and may be maintained on the heat processing plates 212 at a predetermined temperature.

The wafers may be transferred to first and second coating units (S120). For example, the wafers may be transferred from the first and second heat processing units 210a and 210b to first and second coating units 230a and 230b, respectively, by first and second transfer robots 220a and 220b which are installed to be movable along a vertical transfer path.

The first transfer robot 220a may move along the vertical guide rail 221 and draw out the wafer from the heat processing plate 212 of the first heat processing unit 210a. The transfer robot 220a may rotate to face a first direction (e.g., the X direction), and then may move along the vertical guide rail 221 and transfer the wafer to a coating device 232 of the first coating unit 230a. Similarly to the first transfer robot 220a, the second transfer robot 220b may transfer the wafer from the second heat processing unit 210b to the second coating unit 230b.

Spin coating processes may be performed (S130). For example, the spin coating processes may be performed in the first and second coating units 230a and 230b to coat a material layer on each of the wafers.

According to one or more exemplary embodiments of the present inventive concept, the coating devices 232 of the first and second coating units 230a and 230b may discharge a coating material onto the wafer while rotating the wafer. For example, the coating material may include a chemical used for coating the SOH layer.

After performing the spin coating process, the wafers may be transferred to first and second bake units (S140). For example, the wafers may be transferred from the first and second coating units 230a and 230b to first and second bake units 240a and 240b.

The first transfer robot 220a may move along the vertical guide rail 221 and draw out the wafer from the coating device 232 of the first coating unit 230a. The first transfer robot 220a may rotate to face a second direction (e.g., the Y direction) substantially perpendicular to the first direction, and then may move along the vertical guide rail 221 and transfer the wafer to a heat processing plate 242 of the first bake unit 240a. Similarly to the first transfer robot 220a, the second transfer robot 220b may transfer the wafer from the second coating unit 230b to the second bake unit 240b.

A bake process may be performed (S150). According to one or more exemplary embodiments of the present inventive concept, after the wafer is transferred to the heat processing plate 242 and is pre-heated to a desired temperature, the wafer may be transferred from the heat processing plate 242 to a heater 244 and may be heated to a relatively high temperature.

After performing the bake process, the wafers may be transferred to first and second heat processing units (S160). For example, the wafers may be transferred from the first and second bake units 240a and 240b to the first and second heat processing units 210a and 210b.

The first transfer robot 220a may move along the vertical guide rail 221 and draw out the wafer from the heat processing plate 242 of the first bake unit 240a. The first transfer robot 220a may rotate to face a reverse direction (e.g., the Y direction) of the first direction, and then may move along the vertical guide rail 221 and transfer the wafer to the heat processing plate 212 of the first heat processing unit 210a. Similarly to the first transfer robot 220a, the second transfer robot 220b may transfer the wafer from the second bake unit 240b to the second heat processing unit 210b.

After the wafers are transferred to the heat processing plates 212 of the first and second heat processing units 210a and 210b, the wafers may be maintained on the heat processing plates 212 at a predetermined temperature.

Then, the wafers may be unloaded through an index module (e.g., the index module 110) (S170).

According to one or more exemplary embodiments of the present inventive concept, the index robot 130 may transfer the wafers from the first and second heat processing units 210a and 210b to the wafer carrier C. After the wafers including a mask layer formed thereon are received in the wafer carrier C, the wafer carrier C may be transferred to another substrate process device where additional processes may be performed.

A method of manufacturing a semiconductor device using the substrate processing method described above with reference to FIG. 17 will be described below in more detail.

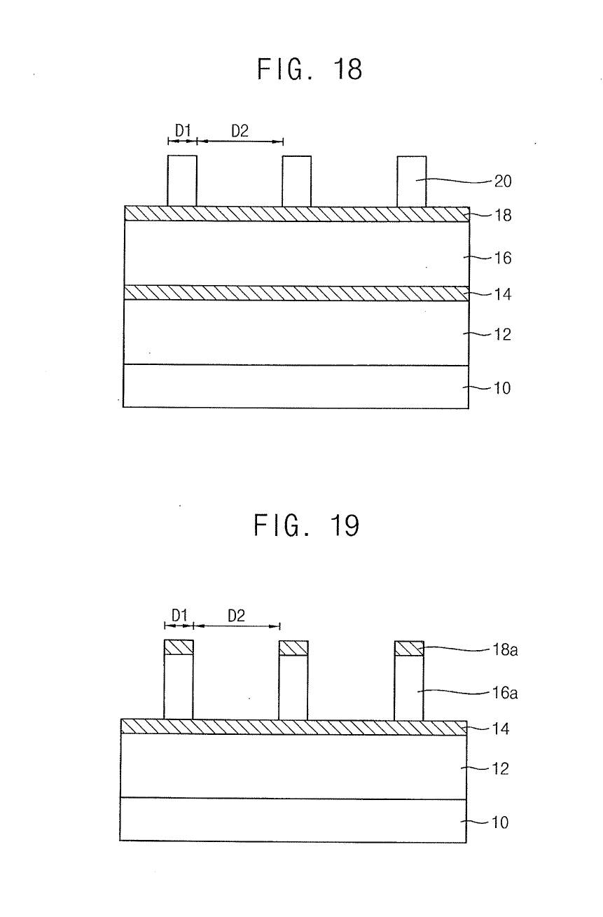

FIGS. 18 to 25 are cross-sectional views illustrating a method of manufacturing a semiconductor device according to one or more exemplary embodiments of the present inventive concept.

Referring to FIG. 18, an etch target layer 12 may be formed on a substrate 10. A lower mask layer 14, a sacrificial layer 16 and an upper mask layer 18 may be sequentially formed on the etch target layer 12. A photoresist pattern 20 may be formed on the upper mask layer 18 by a photoresist process.

The substrate 10 may be a semiconductor substrate (e.g., a silicon substrate, a germanium substrate, a silicon-germanium substrate, a silicon-on-insulator (SOI) substrate, or a germanium-on-insulator (GOI) substrate).

The etch target layer 12 may include an insulating material, a conductive material, and/or a semiconductor material. For example, the insulating material may include silicon oxide, silicon nitride, and/or silicide oxynitride. For example, the conductive material may include one or more metals, metal nitrides, metal silicides, and metal silicon nitrides. For example, the semiconductor material may include polysilicon.

The etch target layer 12 may be formed by a chemical vapor deposition (CVD) process, a plasma enhanced chemical vapor deposition (PE-CVD) process, a low pressure chemical vapor deposition (LP-CVD) process, a high density plasma chemical vapor deposition (HDP-CVD) process, a spin coating process, a sputtering process, an atomic layer deposition (ALD) process, and/or a physical vapor deposition (PVD) process.

The etch target layer 12 may be omitted. For example, the etch target layer 12 may be omitted when the substrate 10 is the layer or structure to be etched. Thus, the term “etch target” may refer to either the etch target layer 12 or the substrate 10.

The lower mask layer 14 may include a material capable of serving as an etching mask for etching the etch target layer 12. That is, the lower mask layer 14 may include a material having a relatively high etching selectivity with respect to the etch target layer 12. Thus, a material included in the lower mask layer 14 may be chosen according to a material included in the etch target layer 12.

For example, the lower mask layer 14 may include silicon nitride or silicon oxynitride. In this case, the lower mask layer 14 may also serve as an anti-reflective layer. The lower mask layer 14 may include silicon oxide. However, the lower mask layer 14 may be omitted.

The sacrificial layer 16 may serve as a mold layer for forming an etching mask, and may be removed after serving as an etching mask. Thus, the sacrificial layer 16 may include a material having a relatively high etching selectivity with respect to the etching mask. The sacrificial layer 16 may include a material that may be relatively easily and relatively selectively removed.

For example, the sacrificial layer 16 may include an amorphous carbon layer (ACL) or a carbon-containing layer. The sacrificial layer 16 may be a spin on hardmask (SOH) layer. For example, the SOH layer may be a hybrid SOH (H-SOH) layer.

The sacrificial layer 16 may be formed on the substrate 10 using the substrate processing system 100 as described with reference to FIGS. 1 to 5, 6A, 6B, 7A, 7B, 7C and 8 to 15. A spin coating process may be performed in each of first and second coating units 230a and 230b to form an organic compound layer on the substrate 10. The organic compound layer may include a hydrocarbon compound containing an aromatic ring, such as a phenyl, benzene, naphthalene, or a derivative thereof. Then, a bake process may be performed in each of first and second bake units 240a and 240b to form the sacrificial layer. After the wafers including the sacrificial layer formed thereon are received in a wafer carrier C, the wafer carrier C may be transferred to another substrate process device where additional processes may be performed to form the upper mask layer 18.

The upper mask layer 18 may include a material capable of serving as an etching mask for etching the sacrificial layer 16. That is, the upper mask layer 18 may include a material having a relatively high etching selectivity with respect to the sacrificial layer 16. For example, the upper mask layer 18 may include silicon nitride or silicide oxynitride. In this case, the upper mask layer 18 may also serve as an anti-reflective layer.

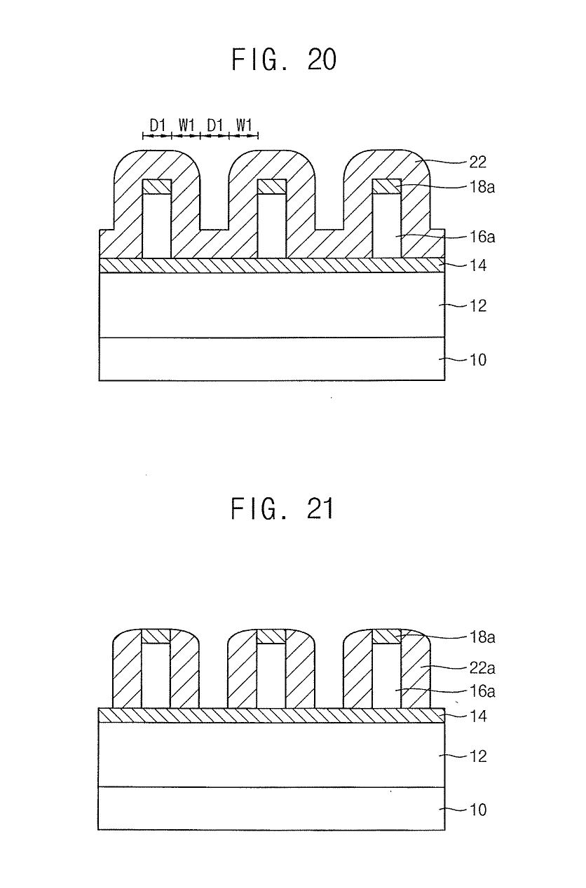

The photoresist pattern 20 may include a line and space pattern, including lines of photoresist. The lines of photoresist may be referred to as “lines of the photoresist pattern 20” herein. The lines of the photoresist pattern 20 may each extend lengthwise in a first direction. A width D1 of each of the lines of the photoresist pattern 20 may be substantially the same as a first target distance between the subsequently formed target layer patterns 12a (see, e.g., FIG. 25). A distance D2 between the lines of the photoresist pattern 20 may be substantially the same as a sum of the first distance D1 and twice a first width W1 (see, e.g., FIG. 20). The first width W1 may be a target width in the second direction of a subsequently formed target layer pattern 12a. For example, the first distance D1 and the first width W1 may be substantially the same as each other and the second distance D2 may be about 3 times the first width W1.

The photoresist pattern 20 may be formed by coating and baking a photoresist material to form a photoresist film, and exposing and developing the photoresist film. The exposure process may use an ArF excimer laser, KrF excimer laser, G-line, I-line, electron beam, or an extreme ultraviolet (EUV) beam to expose the photoresist film.

Referring to FIG. 19, the upper mask layer 18 may be anisotropically etched using the photoresist pattern 20 as an etching mask to form an upper mask 18a. During the etching process, the photoresist pattern 20 may be partially etched. The sacrificial layer 16 may be anisotropically etched using the upper mask 18a as an etching mask to form a sacrificial layer pattern 16a. For example, the upper mask 18a may remain on the sacrificial layer pattern 16a after the sacrificial layer 16 has been selectively etched.

According to one or more exemplary embodiments of the present inventive concept, a plurality of sacrificial layer patterns 16a may be formed, and each of the sacrificial layer patterns 16a may extend in the first direction. Each of the sacrificial layer patterns 16a may have a width in the second direction substantially the same as the first distance D1. A distance between the sacrificial layer patterns 16a may be substantially the same as the second distance D2. The lines of the sacrificial layer pattern 16a may be referred to herein as the sacrificial layer line patterns 16a.

Referring to FIG. 20, a mask layer 22 may be conformally formed on the sacrificial layer line patterns 16a, the upper mask 18a and the lower mask layer 14. When the mask layer 22 is formed to have a substantially uniform thickness, portions of the mask layer 22 on top edges of the sections (e.g., “segments”) of the upper mask 18a may be rounded. For example, the radius of curvature of the portions of the mask layer 22 on the top edges of the segments of the upper mask 18a may be substantially the same as the thicknesses of all other portions of the mask layer 22.

The mask layer 22 may be formed by an ALD process or a CVD process. For example, when the target layer pattern 12a has a width of about several nanometers to about tens of nanometers, the mask layer 22 may be formed by an ALD process.

The mask layer 22 may serve as an etching mask for etching the lower mask layer 14. Thus, the mask layer 22 may have a relatively high etching selectivity with respect to the lower mask layer 14.

In an example in which the lower mask layer 14 is not formed, the mask layer 22 may serve as an etching mask for etching the etch target layer 12. In this case, the mask layer 22 may have a relatively high etching selectivity with respect to the etch target layer 12.

The mask layer 22 may have a thickness substantially the same as the first width W1. A portion of the mask layer 22 on sidewalls of each of the sacrificial layer line patterns 16a may have the first width W1 in the second direction. A distance in the second direction between portions of the mask layers 22 on opposite sidewalls of the sacrificial layer patterns 16a may be substantially the same as the first distance D1.

Referring to FIG. 21, the mask layer 22 may be anisotropically etched until a top surface of the lower mask layer 14 is exposed to form preliminary mask patterns 22a on both sidewall surfaces of each of the sacrificial layer patterns 16a.

Neighboring ones of the preliminary mask patterns 22a may have significantly different shapes from on another because the portions of the mask layer 22 on the top edge portion of each of the segments of the upper mask 18a may be rounded. Each of the preliminary mask patterns 22a may be asymmetric with respect to a plane passing through a central point of each of the preliminary mask patterns 22a in the second direction and extending in the first direction. Thus, the portion (e.g., a first portion) of the top surface of each of the preliminary mask patterns 22a between the plane and the closest sidewall surface of the sacrificial layer patterns 16a in the second direction may be higher than the portion (e.g., a second portion) of the top surface away from the sidewall surface with respect to the plane. Thus, the height of the top surface of each of the preliminary mask patterns 22a, as measured from a reference plane such as the upper surface of the substrate 10, may gradually decrease from the first portion toward the second portion thereof.

After forming the preliminary mask patterns 22a, the upper masks 18a may remain on the sacrificial layer patterns 16a, respectively.

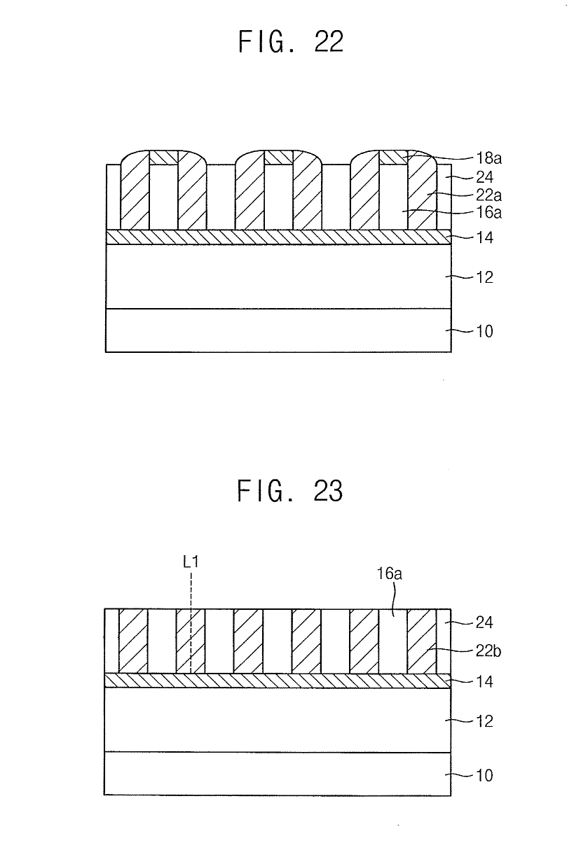

Referring to FIG. 22, a filling layer may be formed on the lower mask layer 14 to fill a space between the preliminary mask patterns 22a.

According to one or more exemplary embodiments of the present inventive concept, the filling layer may include a material substantially the same as a material of the sacrificial layer pattern 16a. For example, the filling layer may include an ACL layer or a carbon-containing layer. The filling layer may be formed on the substrate 10 using the substrate processing system 100 described in more detail above with reference to FIGS. 1 to 5, 6A, 6B, 7A, 7B, 7C and 8 to 15. A spin coating process may be performed in each of the first and second coating units 230a and 230b and a bake process may be performed in each of the first and second bake units 240a and 240b to form the filling layer.

Alternatively, the filling layer may include polysilicon and may be formed by a CVD process.

The filling layer may be planarized by an etch back process until a top surface of the upper mask 18a is exposed to form a filling layer pattern 24 filling the space between the preliminary mask patterns 22a.

Referring to FIG. 23, the upper mask 18a may be removed by an etch back process. Upper portions of the preliminary mask patterns 22a may be etched by an etch back process to form mask patterns 22b having substantially the same shape as each other. During the etch back process, the sacrificial layer line patterns 16a and the filling layer pattern 24 may be partially etched.

Each of the mask patterns 22b may be substantially symmetric with respect to the plane L1 passing through the center point of the mask pattern 22b in the second direction and extending in the first direction. For example, top surfaces of the mask patterns 22b may be substantially coplanar.

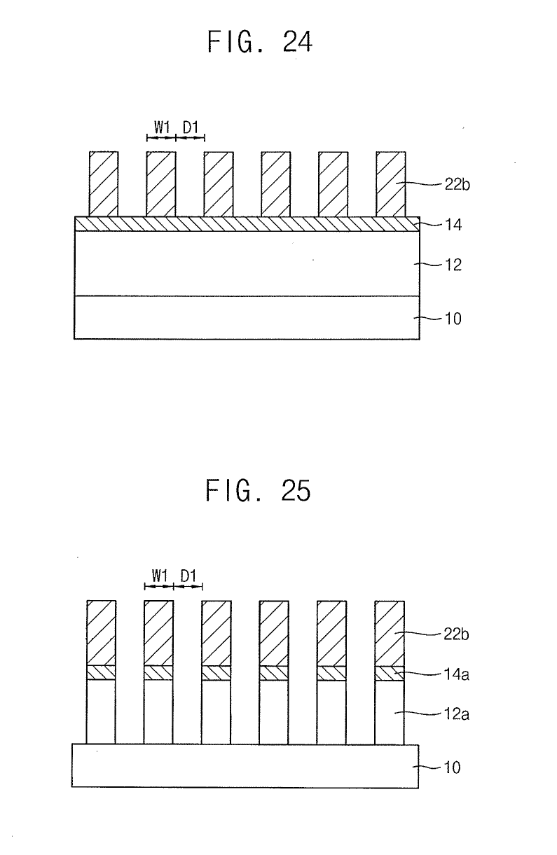

Referring to FIG. 24, the sacrificial layer patterns 16a and the filling layer pattern 24 may be removed, and the mask patterns 22b may remain on the lower mask layer 14. Each of the mask patterns 22b may have the first width W1, and the mask patterns 22b may be spaced apart from each other by the first distance D1.

In an example in which the sacrificial layer line patterns 16a and the filling layer pattern 24 include an ACL or a carbon-containing layer, the sacrificial layer line patterns 16a and the filling layer pattern 24 may be removed by a plasma ashing process.

In an example in which the sacrificial layer line patterns 16a and the filling layer pattern 24 include a polysilicon layer, the sacrificial layer line patterns 16a and the filling layer pattern 24 may be removed by an isotropic etching process.

Referring to FIG. 25, the lower mask layer 14 may be anisotropically etched using the mask patterns 22b as an etching mask to form a lower mask 14a.

The etch target layer 12 may be etched using the lower mask 14a as an etching mask to form the target layer patterns 12a. During the etching process, the lower mask 14a may be partially or completely removed. Each of the target layer patterns 12a may have the first width W1, and the target layer patterns 12a may be spaced apart from each other by the first distance D1.

The substrate processing system in accordance with one or more exemplary embodiments of the present inventive concept may be applied to process a wafer; however, exemplary embodiments of the present inventive concept are not limited thereto, and the substrate processing system may be applied to process various types of substrates such as FPD, or a mask reticle for photomask.

While the present inventive concept has been particularly shown and described with reference to exemplary embodiments thereof, it will be understood by those of ordinary skill in the art that various changes in form and detail may be made therein without departing from the spirit and scope of the present inventive concept

1. A substrate processing system, comprising:
an index module comprising a plurality of wafer carriers, wherein each wafer carrier is configured to support a wafer;
first and second heat processing units disposed adjacent to the index module, wherein each of the first and second heat processing units includes a plurality of first heat processing plates sequentially stacked in a vertical direction;
first and second transfer robots disposed adjacent to the first and second heat processing units, respectively, wherein each of the first and second transfer robots is configured to be movable along a vertical transfer path, and wherein each of the first and second transfer robots is configured to rotate;
first and second coating units disposed adjacent to first sides of the first and second transfer robots, respectively, wherein each of the first and second coating units includes a plurality of coating devices sequentially stacked in the vertical direction; and
first and second bake units disposed adjacent to second sides of the first and second transfer robots, respectively, wherein each of the first and second bake units includes a plurality of second heat processing plates sequentially stacked in the vertical direction.

2. The substrate processing system of claim 1, wherein the second side is adjacent to the first side and the second side extends in a direction different from an extending direction of the first side.

3. The substrate processing system of claim 2, wherein the extending direction of the first side is substantially perpendicular to the extending direction of the second side.

4. The substrate processing system of claim 1, wherein the first and second transfer robots do not travel along a track extending in a horizontal direction substantially perpendicular to the vertical direction.

5. The substrate processing system of claim 1, wherein the first heat processing unit is arranged between the index module and the first transfer robot, and wherein the second heat processing unit is arranged between the index module and the second transfer robot.

6. (canceled)

7. The substrate processing system of claim 1, wherein the index module has a rectangular shape, and wherein the first heat processing unit and the second heat processing unit are arranged along a relatively longer side of the rectangular index module.

8. The substrate processing system of claim 1, wherein the first heat processing plates of the first and second heat processing units comprise cooling plates.

9. The substrate processing system of claim 1, wherein the first and second coating units are arranged to face the index module with the first and second transfer robots disposed between the index module and the first and second coating units, respectively.

10. The substrate processing system of claim 9, wherein the first heat processing unit, the first transfer robot and the first coating unit are arranged in a first line from a side of the index module facing the first and second heat processing units, and wherein the second heat processing unit, the second transfer robot and the second coating unit are arranged in a second line from the side of the index module facing the first and second heat processing units.

11. The substrate processing system of claim 1, wherein the first and second bake units are arranged to face the index module with the first and second transfer robots disposed between the index module and the first and second bake units.

12. The substrate processing system of claim 11, wherein the first heat processing unit, the first transfer robot and the first bake unit are arranged in a first line from a side of the index module facing the first and second heat processing units, and the second heat processing unit, the second transfer robot and the second bake unit are arranged in a second line from the side of the index module facing the first and second heat processing units.

13. The substrate processing system of claim 1, wherein the first transfer robot is configured to rotate to face the first heat processing unit, the first coating unit, and the first bake unit.

14. The substrate processing system of claim 1, wherein the first and second heat processing units are stacked on each other in the vertical direction, and the first and second transfer robots are stacked on each other in the vertical direction corresponding to the first and second heat processing units.

15. (canceled)

16. (canceled)

17. (canceled)

18. (canceled)

19. (canceled)

20. A substrate processing system, comprising:
first and second heat processing units disposed adjacent to an index module, wherein each of the first and second heat processing units includes a plurality of first heat processing plates sequentially stacked in a vertical direction;
first and second transfer robots spaced apart from the first and second heat processing units in a first direction, wherein each of the first and second transfer robots is configured to be movable along a vertical transfer path, and wherein each of the first and second transfer robots is configured to rotate;
first and second coating units spaced apart from the first and second transfer robots in a second direction, wherein each of the first and second coating units includes a plurality of coating devices sequentially stacked in the vertical direction; and
first and second bake units spaced apart from the first and second transfer robots in a third direction different from the second direction, wherein each of the first and second bake units includes a plurality of second heat processing plates sequentially stacked in the vertical direction.

21. The substrate processing system of claim 20, wherein the second direction is substantially perpendicular to the third direction.

22. (canceled)

23. The substrate processing system of claim 20, wherein gates are provided in first sides of each of the coating devices of the first and second coating units, and wherein the first and second coating units are arranged with the first sides of each of the coating devices crossing the second direction.

24. (canceled)

25. The substrate processing system of claim 20, wherein gates are provided in first sides of each of the bake devices of the first and second bake units, and wherein the first and second bake units are arranged with the first sides of each of the bake devices crossing the third direction.

26. (canceled)

27. (canceled)

28. (canceled)

29. (canceled)

30. The substrate processing system of claim 20, wherein the first and second heat processing units are stacked on each other in the vertical direction, and wherein the first and second transfer robots are stacked on each other in the vertical direction corresponding to the first and second heat processing units.

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. (canceled)

43. (canceled)

44. (canceled)

45. (canceled)

46. (canceled)

47. (canceled)

48. (canceled)

49. (canceled)

50. (canceled)

51. (canceled)

52. (canceled)

53. (canceled)

54. A substrate processing system, comprising:
an index module configured to support at least one wafer;
a heat processing unit adjacent to the index module, wherein the heat processing module includes a plurality of first heat processing plates sequentially stacked in a vertical direction;
a transfer robot disposed on a side of the heat processing using opposite the index module;
a coating unit disposed on a first side of the transfer robot opposite the heat processing unit, wherein the coating unit comprises a plurality of coating devices sequentially stacked in the vertical direction; and
a bake unit disposed adjacent to the transfer robot on a second side of the transfer robot that is perpendicular to the first side, wherein the bake unit comprises a plurality of second heat processing plates sequentially stacked in the vertical direction.

55. The substrate processing system of claim 54, wherein each of the first heat processing plates is substantially aligned with a corresponding one of the coating devices and a corresponding one of the second heat processing plates.

56. (canceled)

57. (canceled)

58. (canceled)
